(19) United States
(12) Patent Application Publication
(10) Pub. No.: US 2009/0026912 A1
(43) Pub. Date: Jan. 29, 2009

(54) INTENSITY MODULATED ELECTRON BEAM AND APPLICATION TO ELECTRON BEAM BLANKER

(75) Inventors: Vincenzo Lordi, Livermore, CA (US); Kirkwood Rough, San Jose, CA (US); Xuefeng Liu, San Jose, CA (US); Shem-Tov Levi, Beit hanan (IL)

Correspondence Address: Suiter Swantz/KLA Joint Customer Number;Suiter Swantz pc llo, 14301 FNB Parkway, Suite 220, Omaha, NE, 68154-5299, US

(73) Assignee: KLA-Tencor Technologies Corporation

(21) Appl. No.: 11/829,034

(22) Filed: Jul. 26, 2007

(51) Int. Cl. H01J 37/302; H01J 29/51; H01J 37/30

(52) U.S. Cl. 313/414; 250/492.23

(57) ABSTRACT

Method and apparatus for achieving an intensity modulated electron blanker are disclosed. An apparatus includes a cathode exposed to an activation source to generate an electron beam. Cathode control circuitry adjusts a cathode control amplifier to regulate cathode voltage and the potential of the electron beam. In some approaches the electron beam potential is used to control the blanking frequency, switching speeds, and duty cycle. In another approach electron generating beams directed on to the cathode are modulated to control the electron beam.

### TECHNICAL FIELD

The invention described herein relates generally to the formation of multi-exposure dense lithographic patterns using new approaches and methodologies. In particular, the invention relates to an apparatus and method of operating a controllable electron beam projection device. Also the inventors contemplate systems and methods for generating densely patterned images having a resolution beyond that of existing technologies and as such embodiments of the invention enable increased effective resolution beyond that generally possible using existing tools and technologies. Inventive embodiments enable control of the potential in an electron beam directed onto a digital pattern generator to enable the fabrication of high definition photoresist patterns and/or resultant high definition substrate patterns.

### BACKGROUND

As the density and complexity of microcircuits continue to increase, the photolithographic processes used to print circuit patterns become more and more challenging. Previous technologies and thinking in the art has required denser and more complex patterns to achieve the formation of the denser circuits consisting of smaller pattern elements packed more closely together. Such patterns push the resolution limits of available lithography tools and processes and place serious burdens on the design and quality of the devices used to fabricate such patterns.

In one prior art approach an electron beam is used to write a pattern onto a photoimageable surface to enable patterning. One such approach relies upon an extremely high voltage cathode set at a high voltage to produce an electron beam that is directed through an aperture to produce a beam that writes the desired pattern on a target (that lies in the path of the beam).

Such a high voltage cathode produces the electron beam directed to an aperture. But, when the pattern requires that no beam be directed onto the target, the beam must be impeded. Some manufacturers (for example, Applied Materials, Inc. of San Jose, Calif.) have attempted to achieve this by applying an appropriate voltage at the aperture in order to deflect the beam off of the target. A voltage sufficient to establish a deflecting electrical field must be applied at the aperture in order to deflect the flow of electrons at the aperture. The problem with this process is that the beam deflection is difficult to actuate at a very high rate of speed. Systems having switching speeds of on the order of 50 picoseconds or less and having a repetition rates on the order of 100's of megahertz (MHz) are difficult to implement using existing technologies. Existing systems capable of applying a 50 volt potential within 50 (or less) picoseconds in a duty cycle of 100 or 200 MHz are, at this date, simply not effective. Moreover, in the time the beam is deflected, a residual beam artifact remains as the beam moves. This artifact produces numerous difficulties that have proven difficult to solve and result in unsatisfactory patterns being formed. Furthermore, such systems produce a resultant electron beam having substantial residual beam energy impinging on the target resulting from the finite time it takes to effectively deflect an electron beam. This has proven unworkable.

Moreover, when a beam is deviated from the aperture by a magnetic field many other detrimental effects are observed. For example, the switching speeds of such deviated beams do not operate efficiently at the required frequencies (hundreds of MHz) and, as explained previously, the motion of the beam as it is deviated generates numerous artifacts that result in pattern errors that are difficult, if not impossible, to correct for.

The inventors postulate that a system that does not demonstrate some or all of these drawbacks would be helpful and present a significant advance over the current state of the art. Accordingly, the embodiments of invention present substantial advances over the existing methodologies and overcome many limitations of the existing electron beam blanker arts. These and other inventive aspects of the invention will be discussed herein below.

### SUMMARY OF THE INVENTION

In accordance with the principles of the present invention, methods and apparatus for achieving high-speed blanking and dynamic pattern generation in reflection electron beam lithography are disclosed.

Numerous aspects of the present invention are described in detail in the following description and drawings set forth hereinbelow.

In one embodiment, the invention teaches a blanker apparatus including a cathode for generating an electron beam having a cross-section. A cathode activation source is arranged to controllably cause the cathode to produce an electron beam that is directed through an aperture in a focusing electrode. A cathode control amplifier regulates the voltage at the cathode to regulate the potential of the electron beam. Cathode control circuitry adjusts the cathode control amplifier to enable regulation of the potential of the electron beam.

In another embodiment, the blanker above is configured to direct an electron beam onto a dynamic pattern generator to produce a patterned electron beam that is projected onto a target to achieve pattern transfer.

In another embodiment, the invention discloses a cathode system configured for blanking. The system includes a cathode that emits electrons when exposed to radiation and a cathode activation source for controllably activating the shaped cathode to produce the electron beam. Control circuitry is configured to adjust the cathode activation source to regulate the electron beam produced by the shaped cathode.

In another embodiment, the invention discloses another cathode system configured for blanking. The system includes a cathode that emits electrons in an electron beam when exposed to radiation. A cathode activation source is used to controllably activate the cathode to produce the electron beam. Control circuitry adjusts the cathode activation source to regulate the electron beam produced by the cathode.

In a method embodiment of the invention, high speed blanking in a reflection electron beam lithography device is performed as follows. A cathode is activated to generate a continuous electron beam that is directed onto a digital pattern generator, having an array of programmable elements configured to selectively imprint patterns onto the continuous electron beam to form patterned electron beam. The elements of the array are adjusted to selectively imprint patterns onto the continuous electron beam to form the patterned electron beam. A voltage level is modulated at the cathode to controllably adjust the potential of the continuous electron beam such that when the voltage level is biased to a first voltage level no patterned electron beam is produced and such that when the voltage level is biased to a second voltage level the patterned electron beam is produced. This patterned electron beam can be directed onto a target to achieve electron beam pattern transfer.

In another embodiment, the invention teaches a method for performing high speed blanking in a reflection electron beam lithography device, the method comprises activating a photo cathode with a laser to generate an intermittent electron beam and directing the intermittent electron beam onto a digital pattern generator. Programmable elements of the digital pattern generator are configured to selectively imprint patterns onto the intermittent electron beam to form patterned electron beam. The laser output is modulated to controllably gate the production of electrons by the photo cathode such that when the laser is off the intermittent electron beam is off and no patterned electron beam is produced and such that when the laser is on the intermittent electron beam is on and the patterned electron beam is produced.

These and other aspects of the present invention are described in greater detail in the detailed description of the drawings set forth hereinbelow.

### BRIEF DESCRIPTION OF THE DRAWINGS

The following detailed description will be more readily understood in conjunction with the accompanying drawings, in which:

FIGS. 1(a) & 1(b) are schematic depictions of an embodiment of an electron beam and electron blanker device.

FIG. 1(c) depicts an example of an on/off cycle and its relationship to “repetition rate” and duty cycle in accordance with the principles of the invention.

FIG. 2 is block diagram depiction of a blanker cathode embodiment of the invention.

FIG. 3 is block diagram depiction of a REBL device employing a suitable electron beam and electron blanker cathode embodiment of the invention.

FIG. 4(a) is schematic diagram depiction of a REBL device employing a blanker cathode embodiment of the invention.

FIGS. 4(b) & (c) are block diagrams illustrating alternative embodiments of cathode activation sources and cathodes in accordance with embodiments of the invention.

FIG. 4(d) is schematic diagram depiction of a REBL device employing a photoemissive cathode embodiment of the invention.

FIG. 5(a) is a simplified depiction of a dynamic pattern generator utilized in some embodiments of the invention.

FIGS. 5(b) & 5(c) are simplified illustrative depictions of a selectively biased cathode interacting with the dynamic pattern generator utilized in some embodiments of the invention.

FIG. 6 is a simplified depiction of the shaped pattern and orientation produced by a shaped cathode embodiment of the invention as projected onto a DPG in accordance with the principles of the invention.

It is to be understood that, in the drawings, like reference numerals designate like structural elements. Also, it is understood that the depictions in the Figures are not necessarily to scale.

### DESCRIPTION OF SPECIFIC EMBODIMENTS

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the invention.

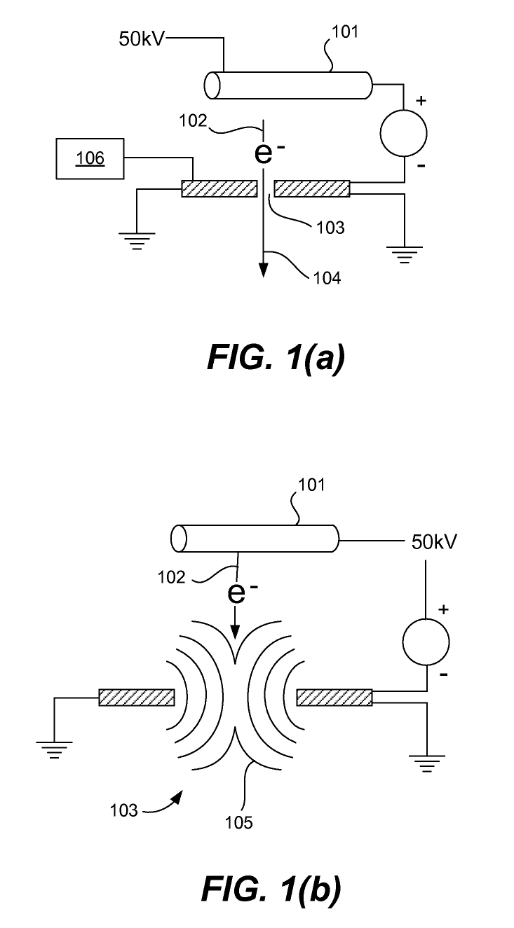

The following detailed description describes various embodiments of a method and approach for obtaining a highly controllable electron beam. Additionally, disclosure of many embodiments of a highly effective electron beam blanker are disclosed. In one approach an electron beam is used to write a pattern onto a photoimageable surface to enable patterning. As depicted in FIG. 1(a), one such approach relies upon an extremely high voltage cathode 101 set at a voltage in the range of 50 to several hundred kV (the inventors point out that much higher voltages can also be employed) that produces an electron beam 102 that is directed through an aperture 103 to produce a beam 104 that writes the desired pattern on a target (that lies in the path of the beam).

As illustrated in FIG. 1(b), the high voltage cathode 101 produces the electron beam 102 directed to an aperture 103. But, when the pattern requires that no beam be directed onto the target, the beam is turned off. Control circuitry 106 can be used to selectively apply a voltage at the aperture. A voltage sufficient to establish a pinching electrical field 105 must be applied at the aperture 103 in order to block the flow of electrons 102 through the aperture. In order to completely block the beam 102 voltages of 50 volts or greater are required at the aperture 103. The beam 102 must be switchable, on and off, at an extremely high rate of speed, which in general is difficult to achieve. For example, in one embodiment a switching speed (defined as the average rise and fall time) of on the order of 50 picoseconds or less and having a pulse repetition frequency (or repetition rate) on the order of 100's of megahertz (MHz) is used.

The inventors have provided FIG. 1(c) to illustrate the concepts of pulse repetition frequency (or “repetition rate”) and duty cycle as employed herein. By “repetition frequency” we mean the instantaneous frequency of a full on-off pulse cycle. “Duty cycle” refers to the percentage of time in a full on-off cycle that the beam is on. In FIG. 1(c) the x-axis 110 refers to the time domain and the y-axis 111 references the signal intensity. Signal 112 refers to a near square wave signal having very short rise and fall times. T_{full} (113) refers to the time period of a full on-off cycle. Accordingly, a “repetition rate” is defined as 1/T_{full} (in Hz). Referring again to FIG. 1(c), tᵣ (114) and t_{f} (115) are, respectively, the pulse rise and fall times and the associated switching speed is defined as (tᵣ+t_{f})/2. Tₒₙ (116) refers to the “on” time of the pulse. Accordingly, “duty cycle is” defined as ratio of “on” time 116 to time of a full cycle 113 (i.e., Tₒₙ/T_{full}) and is given as a percentage.

In the proposed variable speed, variable duty cycle system embodied in aspects of the present invention, T_{full} (113) and Tₒₙ (116) can be varied on a pulse-to-pulse basis. This grants extraordinary flexibility and utility to embodiments of the present invention. Accordingly, the quantities “repetition rate” and “duty cycle” can be varied on a pulse-to-pulse basis and defined as instantaneous quantities which that can be varied over time.

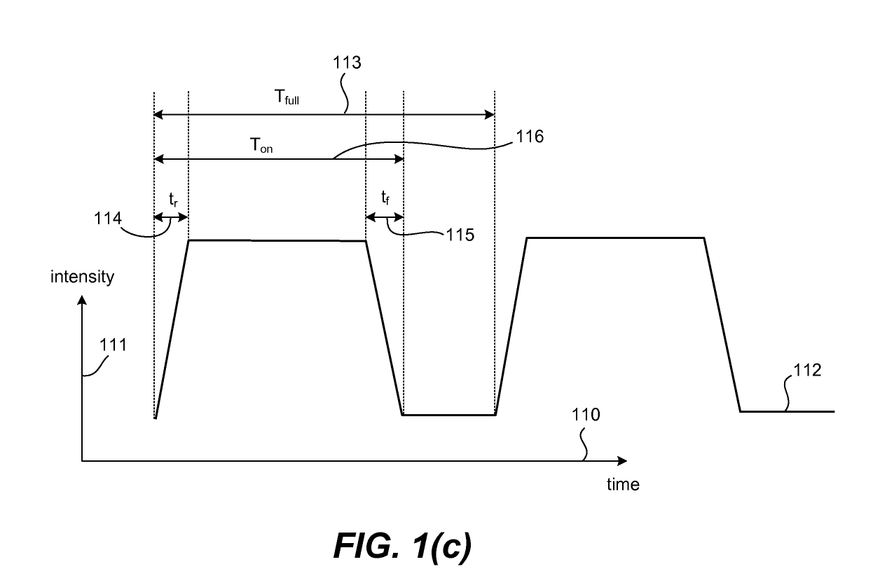

The following detailed description describes various embodiments of a method and approach for obtaining a highly controllable electron beam produced by a blanker. FIG. 2 is simplified block diagram suitable for illustrating some aspects of the invention. A blanker apparatus 200 constructed in accordance with the principles of the invention includes a cathode 202. The cathode 202 is typically a shaped cathode which is useful in generating an electron beam having a precise cross-sectional dimension. The cathode 202 is in operative communication with a cathode activation source 201. The cathode activation source 201 is arranged and configured to enable the cathode 202 to produce the requisite electrons that form an electron beam 206 that is directed through an aperture 203 onto an appropriate target (not shown in this view). Additionally, the cathode 202 receives voltage adjustments from a voltage control amplifier 204. Also, the system further includes cathode control circuitry (broadly used to describe electrical, optical, and electro-optic signal transmission systems and components) 205 configured to control the voltage control amplifier 204. Such control circuitry 205 can include, replace, or otherwise augment the control circuitry 106 of FIG. 1 if desired. The purpose of the voltage control amplifier 204 is to make alterations in the potential of the electron beam 206 to modulate the beam potential with respect to a digital pattern generator (not shown in this view). The detailed reasons for this feature (and its advantages) will be discussed in detail elsewhere in this patent.

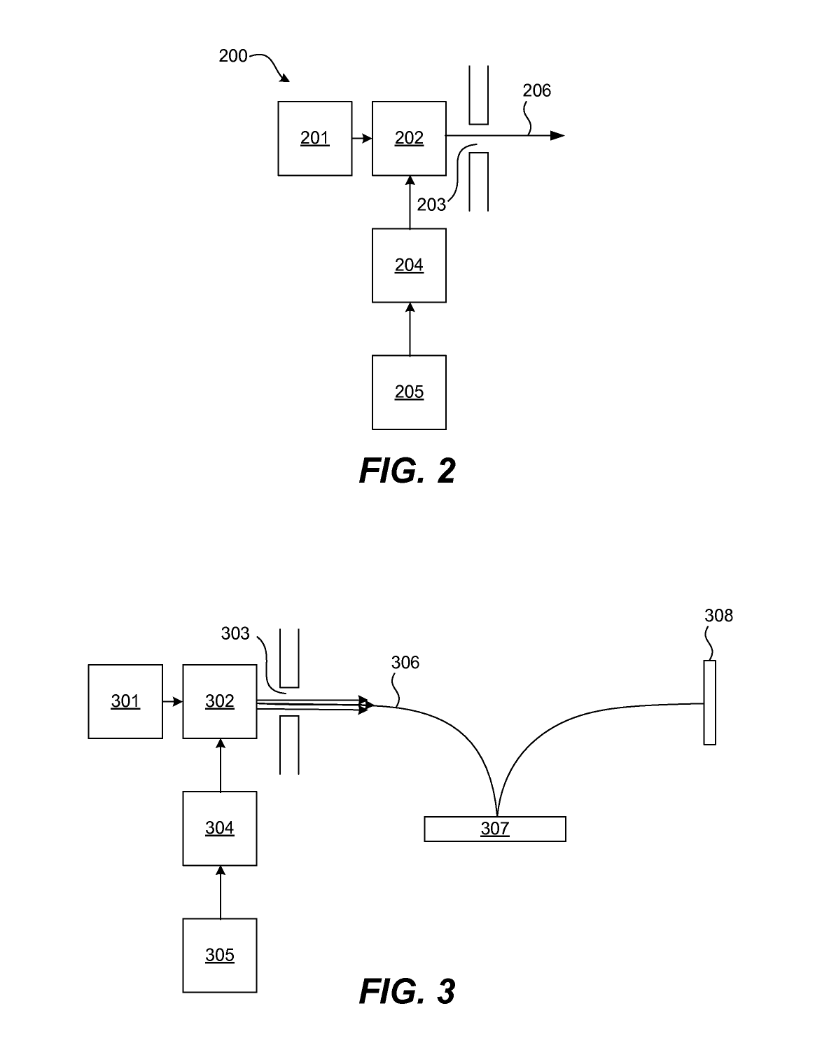

FIG. 3 is another simplified block diagram suitable for illustrating some aspects of the invention. In particular the apparatus depicted in FIG. 2 is applied to a reflection electron beam lithography (REBL) device incorporating a digital pattern generator to impress a pattern onto the electron beam as it writes to a target substrate. For example, in the depicted embodiment, a blanker apparatus such as described in FIG. 2 is employed to generate an electron beam that has a pattern impressed upon it by a digital pattern generator and the patterned beam is then directed onto a target such as a semiconductor wafer having a layer of photoimageable material formed thereon (e.g., photoresist) or some other suitable target substrate. As shown and described here, a cathode activation source 301 (e.g., source 201 of FIG. 2) is arranged in operative communication with a cathode 302 (e.g., cathode 202 of FIG. 2) to generate an electron beam 306 (e.g., electron beam 206 of FIG. 2). Such cathodes include, but are not limited to, a shaped cathode (which is useful in generating an electron beam having cross-sectional dimension that generally matches the shape of the cathode 302). The cathode activation source 301 is activated to cause the cathode 302 to produce electrons 306. The electrons form the electron beam 306 that is directed through an aperture (i.e., a focusing electrode) 303 (e.g., the focusing electrode that can include aperture 203 of FIG. 2) onto the digital pattern generator (DPG) 307 (this will be described in greater detail later). Generally, the path of the electron beam 306 is bent by the presence of a carefully constructed electromagnetic field configured to direct the beam 306 onto the DPG 307 where a pattern is selectively impressed onto the beam 306. The inventors point out that although in most embodiments the beam 306 is directed on to a DPG 307, other embodiments contemplate that the target 307 is merely a plate or other suitable target surface that can be used to either absorb the entire beam or reflect the entire beam without introducing a pattern. In any case, the same electromagnetic field can be used to direct the patterned beam 306 onto a subject 308 (which can be a wafer, a mask substrate, a screen, or any other substrate) where a pattern can be transferred using the beam 306. Implementations of this invention can be used to accomplish (without limitation) patterning of a semiconductor wafer, patterning of a mask substrate to form mask reticles, and numerous other pattern transfer processes. As described briefly above, the potential of the electron beam 306 is modulated at the cathode 302 using a voltage control amplifier 304 (e.g., amplifier 204 of FIG. 2) that is controlled by cathode control circuitry (broadly used to describe electrical, optical, and electro-optic signal transmission systems and components, e.g., as 205) 305. Aspects of this embodiment are discussed in greater detail below.

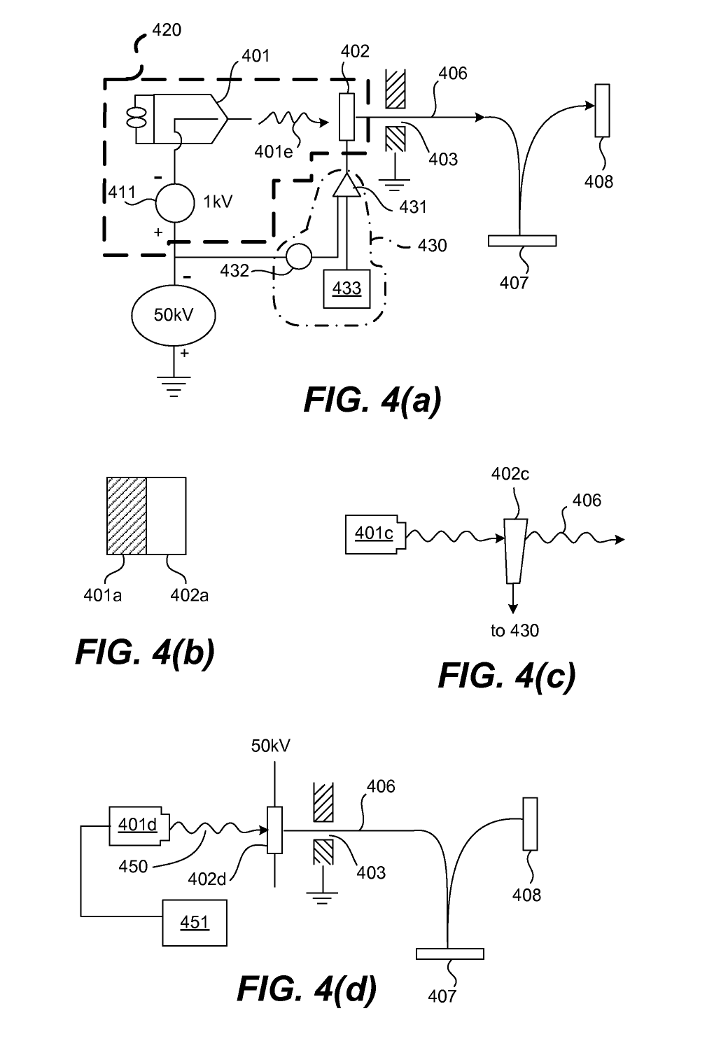

These embodiments are explained in greater detail as follows. FIG. 4(a) is another simplified block diagram suitable for illustrating one embodiment of the invention. As shown and schematically described here, a cathode activation source 401 (e.g., source 201, 301) is a cathode arranged to generate a stream of electrons 401e that impinge on cathode 402 (e.g., 202, 302) to generate an electron beam 406 (e.g., 206, 306). In this embodiment, the cathode 402 can be a thermionic cathode. Such a thermionic cathode comprises a thermionic material that emits electrons when subjected to appropriate heating conditions. For example, the cathode can be exposed to an electron beam to generate heating. Typical thermionic cathode materials include (but are not limited to such) metals e.g., tantalum, yttrium, tungsten, and so on. The cathode 402 is biased with, for example, a large negative base voltage potential (e.g., 50 kilovolts (kV)). Also, in some implementations, the cathode 402 can be resistively grounded 402g (in one example embodiment illustrated here with a 50Ω resistor) to prevent reflective current effects. Moreover, the activation source 401 includes a smaller power source 411 (for example, as depicted illustratively here, adjustable to 1 kV) configured to bias the electrons 401e toward the cathode 402 where they heat the cathode. In this example, the activation source 401 could be biased a further negative 1 kV (e.g., at −51 kV) thereby propelling the electrons 401e toward the cathode 402.

An advantage of such thermionic heating is that it can be arranged such that the distribution of the electrons 401e is generally equal across the entire cathode 402. This enables relatively uniform heating distribution across the electrode which in turn enables a relatively even distribution of produced electrons 406. And another advantageous feature of this direct thermionic heating (with the electrons 401e) is that the energy spread for the electrons produced by the cathode 402 by such heating have a narrow energy distribution. By this, the inventors mean that the voltage range for the electrons produced at 402 is not subject to much energy variance. For example, in one embodiment, the energy spread (range of voltages) in the produced electrons varies by less than 0.25 V. Additionally, prior art electrically activated cathodes also experience marked voltage gradients across the cathodes. This commonly results in a substantial gradient in the voltages imparted to the produced electrons. Accordingly, in prior art systems large voltage variances are experienced by the produced electrons (e.g., tens of volts). Moreover, the energy spread suffers from a physical dimension wherein the spread has a geometric distribution based on the shape of the electrode and the physical characteristics of the electrical gradient across the electrode. State of the art electron beam “optics” are hard pressed to obtain suitable focus of the resultant electron beam across such a large voltage gradient/energy spread. Accordingly, the discussed thermionic heating approach (e.g., with an electron beam) has some advantages over prior approaches.

Additionally, the voltage of the produced electron beam 406 is modulated at the electrode 402 by using a controllable amplifier system (for example 204, 205 or 304, 305) 430. Such a system 430 typically includes an amplifier 431 and circuitry including a biased amplifier power source 432 and control “circuitry” (that may include, optical elements, or RF communication elements, as well as a wide range of other control elements) 433. In one example implementation, the amplifier 431 can comprise a high frequency 5V RF amplifier biased, for example, to a negative 2.5 volts (e.g., using a microwave amplifier). This enables the amplifier to be modulated by an amplifier power source 432 in a range between, for example, about −2.5 volts and +2.5 volts. Other voltage ranges can be used, but ranges that can be modulated between ±1.5-2.5 volts are preferred. In one implementation, the amplifier is controlled by circuitry 433 arranged to enable the amplifier 431 to operate with a pulse frequency of at least 100 mega hertz (MHz) (but preferably in the range of about 200-400 MHz with most preferred embodiments having a duty cycle modulated from 0-100% and having voltage modulation from about −2.5 volts to +2.5 volts with switching speeds in the range of 40 picoseconds (ps) or less (in a selected example a rise time (an example switching speed) ranges between about 25 to 35 ps)). Square wave patterned voltage signals are preferred due to their ability to obtain quick rise and fall times which accordingly result in very small amounts of intermediate voltages (i.e., such square waves generate effectively on and off states with very little intermediate voltage between the “on” and “off” states).

The inventors point out that such embodiments can enable a pulse repetition frequencies of in the range of 200-400 MHz. In fact, embodiments of the type disclosed herein, enable a great degree of flexibility of selecting repetition rates that enable extremely high repetition rates (e.g., on the order of 100's of MHz using embodiments that employ thermionic cathodes with voltage regulation or even higher repetition rates (up into several GHz to tens of GHz) using the laser or optical beam controlled embodiments described below) as well enable extremely high switching rates (short rise and fall times) and enable arbitrary duty cycles. Thus, embodiments of the invention enable the easy adjustment of the repetition rates to enable variable repetition rates as well as very high repetition rates and variable duty cycles.

In one embodiment, the circuitry 433 includes a pulse generator which is configured to control the blanking frequencies of the electrode (via modulating the amplifier 431) and communication circuitry configured to control the amplifier. Due to the very high potentials of the system such control circuitry is chosen with some care. In one example, the inventors contemplate the control circuitry being “photonic” in nature. For example, a pulse generator can be used to operate a laser (or an optical beam such as generated by an LED or other convenient source) which emits a control beam that can be transmitted through a fiber optic line to an optical receiver which receives the optical signal and communicates electrical signals to the amplifier 431 which is then used to modulate the cathode 402. Other optical configurations or layouts can be employed. However, the circuitry 433 is not limited to optically based systems. The inventors point out that all that is necessary is that modulation instructions be provided to the amplifier 431 by the circuitry 433. In another embodiment, the control circuitry can employ radio frequency or microwave devices. The inventors further contemplate that other signal transmission schemes compatible with high potential systems can be employed.

The electron beams 406 so created and modulated are directed through an aperture 403 (similar to 203, 303) and then onto a dynamic pattern generator 407 (or other suitable target substrate) where a pattern is impressed upon the beam as needed and then directed onto a subject 408 (which can be a wafer, a mask substrate, or any other substrate including patternable substrates) where a pattern can be transferred using the beam 406. Implementations of this invention can be used to accomplish for example, without limitation, patterning of a semiconductor wafer, patterning of a mask substrate to form mask reticles, and numerous other pattern transfer processes. Many details of such pattern transfer are well explained in pending patent applications and patents. Examples of certain Dynamic Pattern Generators (DPG's) which embody Direct Write (DW) e-beam lithography are discussed briefly as follows. In one example, the dynamic pattern generator 407 is used as in reflective electron beam lithography (REBL). One such new device is described in the U.S. Pat. No. 6,870,172 entitled “Maskless Reflection Electron Beam Projection Lithography” dated Mar. 22, 2005 which is hereby incorporated by reference for all purposes, including, a specific illustration of a REBL device. Further DPG embodiments are depicted in the U.S. patent application Ser. No. 10/851,041, entitled “Reflective Electron Patterning Device and Method of Using Same” by Harald F. Hess et al, filed on May 21, 2004 and also U.S. patent application Ser. No. 11/391,976, entitled “Dynamic Pattern Generator for Controllably Reflecting Charged-Particles” by Vincenzo Lordi, filed on Mar. 28, 2006 both of which incorporated by reference for all purposes. Additionally, as pointed out above with respect to DPG 307, embodiments of the invention can employ targets 407 that do not impress a pattern onto the beam, but merely operate as an “on/off” switch.

Continuing with description of FIG. 4(a), the cathode 402 emanates a continuous electron beam 406. In one embodiment, the target 407 is a DPG and the modulation of the beam controls the operation of the DPG 407. For example, if the control amplifier 431 biases the system to a more negative level (e.g., −2.5V) the electron beam potential is such that no electrons are reflected by the DPG 407. In other words, at this high negative bias the electrons are driven into the DPG 407 and the individual bias on each of the tiny elements of the pattern generation array are not sufficient to produce reflected electrons. In other words no signal (no electron beam) is produced. However, when the control amplifier 431 biases the system to a more positive level (e.g., +2.5V) the electron beam potential is such that electrons can now be selectively reflected or absorbed depending on the voltage that is selectively applied to each array element of the pattern generation array. Thus, some electrons will be reflected and others not in accordance with a dynamically changing pattern formed by the array. In this way, a pattern can be impressed on the beam and the resultant patterned beam can then be used to pattern a target substrate 408. This is particularly attractive because the electron beam is constantly operating (rather than being selectively deflected as in other approaches). Thus, the control amplifier 431 is used to bias the system so that the determinant in electron reflection is the potential applied to the individual elements of the DPG 407. Thus, only selected electrons are reflected by the DPG 407. In other words when the control amplifier is biased “off” (with a high enough negative bias), the current is on, but it is sufficient to override any voltage applied to the individual elements of the light selection array. In such a case, because no electrons leave the array, the focusing optics and the status of the light selection array are irrelevant as there is no beam to operate on. In the other, “on” case (when the control amplifier is biased with a high enough positive bias), the current is also on, but the presence or absence of the electron beam is geometrically specified by the presence or absence of a voltage applied to the individual elements of the light selection array. In this way, the voltages selectively applied to the individual elements of the array are determinative of the pattern of the resultant electron beam. In such case, the electron beam (that leaves the DPG) has a narrow energy spread enabling a simplified set of focusing optics to enable a focused and patterned electron beam to be directed onto the target 408.

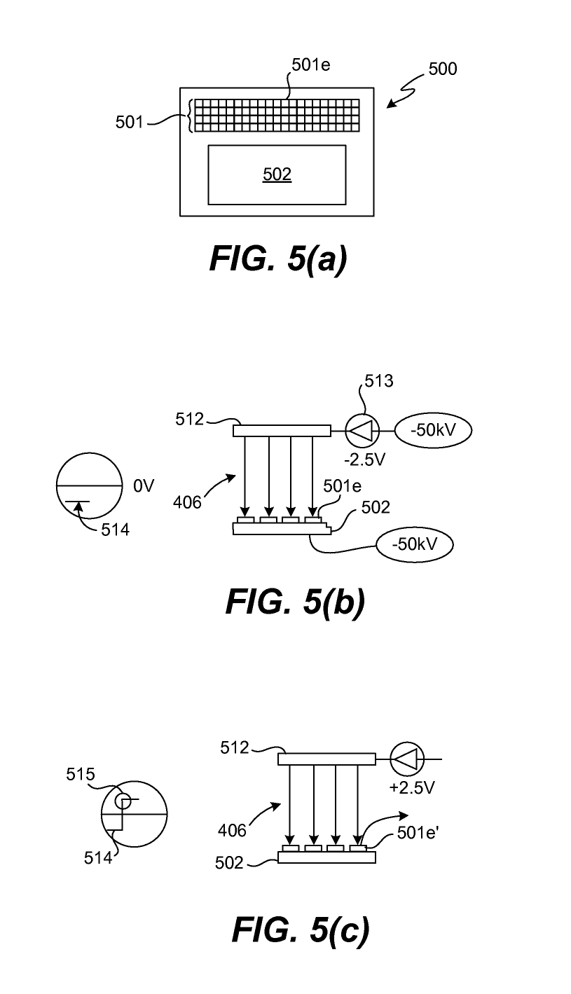

FIG. 5(a) is a simplified depiction of one example implementation of a dynamic pattern generator (DPG) 500 constructed in accordance with the principles of the invention. The depicted DPG 500 includes a pattern generation array 501 including a multiplicity of pattern generation elements 501e. As is extensively described in the forgoing applications and patents, each of these elements 501e comprises a conductive surface configured such that a voltage can be applied individually to each element as needed to establish a desired pattern in a resultant beam. Typically, a negative bias is applied to obtain reflection in electrons directed onto the pattern generation elements 501e and a positive bias is applied to elements 501e that will absorb electrons (thus, subtracting them from the resultant electron beam). In this way an electron beam projected onto the pattern generation array 501 has a pattern impressed thereon by the configuration of the pattern generation elements 50e. Typically, various control circuitries 502 can also be included on the DPG 500. Such circuitry 502 can optionally be formed on layers beneath the pattern generation array 501 to form a more compact structure if desired.

Referring to the simplified illustrations of FIG. 5(b) a large base voltage potential (e.g., −50 kV) is applied to an electrode 512 (analogous to 402 and so on). Also a DPG 502 with an array of pattern generation elements 501e is placed at a similarly high potential (e.g., −50 kV) and the electron beam 406 is directed onto the DPG through the aperture (not shown here). The patentees explain that by applying an electrical potential 514 sufficiently negative (using amplifier 513 e.g., 432 etc.) to the electrode 512 the electron beam 406 overrides the potentials applied at the pattern generation elements 50e and “drives” the electrons 406 into the DPG 502. Thus, no reflected beam is produced. In other words, the DPG is effectively “off” despite being subjected to a continuous electron flow from the electrode 512. In some implementations, the sufficiently negative electrical potential is about −2.5V. The inventors point out that other voltage potentials can be applied and also point out that voltages in the range of −1V to −3V are sufficiently negative.

Moreover, referring to FIG. 5(c), which is a simplified illustration analogous to that of FIG. 5(b), the electrical potential 515 is subjected to a positive bias (using amplifier 513 e.g., 432 etc. to, for example, apply a +2.5V or other suitable level of bias). This enables a sufficient drop in (negative) potential in the electron beam 406 such that the potentials applied at the pattern generation elements 50e enable a selective patterning of the electron beam (such as schematically depicted by element 502e′). Thus, the DPG 502 produces a patterned reflected beam. In other words, the DPG is effectively “on”. In some implementations, a sufficient positive electrical potential is about +2.5V. The inventors point out that other bias voltage potentials can be applied (e.g., although not limited to such, voltages in the range of +1V to +3V are sufficiently positive). It should be noted that the inventors contemplate that the change in potential (e.g., from −2.5V to +2.5 as illustrated by 514, 515) should occur on the order of picoseconds (ps). For example, a rise or fall time should be less than 40 ps (a range of about 25-50 ps is suitable with a range of about 25-35 ps being preferred). At pulse repetition frequencies of 200-400 MHz (or greater) rise times of less than about 0.5-1% of the duty cycle are preferred.

An alternative cathode activation source/cathode arrangement (420) is depicted in FIG. 4(b). In such an arrangement, a cathode activation source 401a can simply be a heating element (e.g., a resistor or the like) placed proximal (here, directly adjacent) to the cathode 402a to effectuate relatively uniform heating of the cathode (and thereby achieve a relatively uniform distribution of produced electrons across the surface area of the electrode 402 and such that the electrons have a narrow energy spread). This is a relatively simple and effective way of generating a uniform electron beam having a cross-section of approximately the same dimensions as the cathode. In one embodiment, the cathode activation source 401a can simply be an aluminum (or e.g., AlNi or other heating source) heating element placed adjacent to the cathode 402a formed of a thermionic material. Many possible material combinations are possible (including, but not limited to, refractory metals and alloys, e.g., Ti, Ta, and others) and contemplated by the inventors.

In yet another alternative embodiment, the combination 420 of cathode activation source and cathode is depicted in FIG. 4(c). In this arrangement, a cathode activation source 401c is a laser (or other photonic element) or other selected radiation producing element arranged in operative combination with a thermionic cathode 402c arranged so that the laser (or other photonic/optical element) achieves relatively uniform heating of the thermionic electrode 402c. This approach also produces a uniform electron beam having a cross-section of approximately the same dimensions as the cathode. The photonically heated thermionic cathode can then be modulated by the amplifier systems describes previously to enable the desired voltage modulation in the beam.

In yet another alternative embodiment depicted in FIG. 4(d), the cathode activation source and cathode are different. In this arrangement, a cathode activation source 401d is a laser (or other photonic element) or other selected radiation producing element arranged in operative combination with a photoemissive (e.g., negative electron affinity) cathode 402d arranged to effectuate relatively uniform photoemission of electrons across the surface area of the electrode 402d when exposed to an appropriate wavelength of light 450. This approach requires a cathode 402d having photoemissive properties and comprises yet another way of generating a uniform electron beam having a cross-section of approximately the same dimensions as the cathode. Advantageously, this implementation allows the laser to operate as the sole regulating means for an electron beam 406 directed onto the DPG 407. In this implementation, much of the complicated circuitry can be removed. Instead of modulating the voltage at the cathode, this embodiment utilizes control circuitry 451 to operate the laser (or other associated optical element) intermittently (on or off) to produce an electron beam of the desired characteristics. A pulse generator and power source are fed into the laser 401d instead of into the cathode. Unlike the prior implementations, this approach does not require constant current (e.g., a constant electron beam) to achieve patterning and dose control. Nor does it rely on the DPG absorbing the electron beam energy when in the “off” state. The produced electron beam is itself switched on and off with sufficient rapidity and rise time. It is also believed that this approach will enable an even smaller energy spread and much higher modulation frequency (10's of GHz or higher) in the resultant electron beam 406 which can be passed through an aperture 403, directed onto a DPG 407 for patterning, and then onto the target 408 as a patterned electron beam.

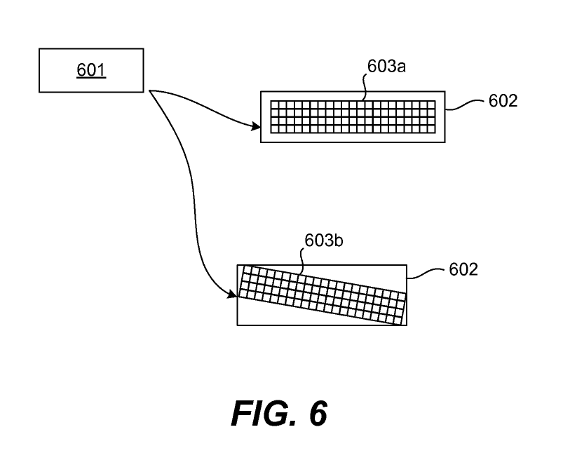

It should be pointed out that in many of the above applications it is advantageous to employ a shaped cathode (which is useful in generating an electron beam having cross-sectional dimension that generally matches the shape of the cathode). The cathode activation source activates the cathode to produce an electron beam that is similar in cross-sectional area to the cathode. For example, a circular cathode will produce an electron beam with a circular cross-section, a rectangular cathode will produce an electron beam with a rectangular cross-section, and so on. FIG. 6 shows an example. A rectangular cathode 601 produces electron beam 602 having a rectangular cross-section. The beam 602 is about the same size as the patterning array 603a to generate an electron beam. In some embodiments, the electron beam 602 having a rectangular cross-section is sized to enable the canting of the patterning array 603b to enable certain patterning effects. The idea being that in general it is a good idea to keep the size of the beam to the smallest size possible to illuminate the DPG so that stray or excess electron interaction can be avoided, and also to maximize the extracted electron current from a given source. This is in contrast to a beam shaping approach using a shaped aperture, which wastes a significant portion of the current by covering it and in addition can also potentially distort the beam, especially at the edges and when the aperture becomes contaminated.

The present invention has been particularly shown and described with respect to certain preferred embodiments and specific features thereof. However, it should be noted that the above-described embodiments are intended to describe the principles of the invention, not limit its scope. Therefore, as is readily apparent to those of ordinary skill in the art, various changes and modifications in form and detail may be made without departing from the spirit and scope of the invention as set forth in the appended claims. Other embodiments and variations to the depicted embodiments will be apparent to those skilled in the art and may be made without departing from the spirit and scope of the invention as defined in the following claims. Further, reference in the claims to an element in the singular is not intended to mean “one and only one” unless explicitly stated, but rather, “one or more”. Furthermore, the embodiments illustratively disclosed herein can be practiced without any element, which is not specifically disclosed herein.

We claim:

1. An apparatus comprising:
a cathode that produces electrons to generate an electron beam;
a focusing electrode that includes an aperture configured to receive electrons from the cathode and regulate the flow of the electrons through an aperture to generate an electron beam, wherein the aperture enables the selective application of a voltage to generate a pinching field that is adjustable to selectively stop or allow the flow of the electron beam through the aperture; and
control circuitry configured to selectively control the voltage at the aperture to enable switching on and off of the electron beam.

2. An apparatus comprising:
a cathode for producing electrons to generate an electron beam;
a cathode activation source arranged to controllably cause the cathode to produce the electrons of the electron beam;
a focusing electrode configured to accelerate the electrons of the electron beam and pass the electron beam through an aperture;
a cathode control amplifier configured to regulate the voltage level at the cathode and thereby regulate the potential of the electron beam; and
cathode control circuitry configured to adjust the cathode control amplifier to enable regulation of the potential of the electron beam.

3. The apparatus of claim 2, wherein during operation, the cathode activation source activates the cathode such that the apparatus produces a continuous electron beam that is directed onto a target.

4. The apparatus of claim 3, wherein exposure of the cathode to the cathode activation source causes the cathode to produce electrons having an energy spread of less than about 0.25 volts, and wherein the cathode control amplifier regulates the potential of the electron beam over a predetermined voltage range.

5. The apparatus of claim 4, wherein the cathode control amplifier regulates the potential of the electron beam over a voltage range of about 5 volts.

6. The apparatus of claim 3, wherein the cathode is a shaped cathode configured so that the electron beam has a shaped cross-section.

7. The apparatus of claim 3, wherein the cathode comprises a thermionic cathode.

8. The apparatus of claim 7, wherein the cathode activation source comprises an electron beam source arranged to direct electrons onto the cathode thereby producing the electron beam.

9. The apparatus of claim 7, wherein the cathode activation source comprises thermal heating source arranged to heat the cathode to a temperature sufficient to enable the production of the electron beam by the cathode.

10. The apparatus of claim 3, wherein the cathode control amplifier regulates the voltage level at the cathode enabling a change in potential of the electron beam to be adjusted over a range of about 5 volts.

11. The apparatus of claim 10, wherein the cathode control amplifier enables changes in potential of the electron beam, wherein the change in potential operates in a range of about 5 volts with a rise time of less than about 40 picoseconds.

12. The apparatus of claim 10, wherein the cathode control amplifier enables changes in potential of the electron beam at a rate of at least 100 megahertz.

13. The apparatus of claim 3, wherein the target enables the entire electron beam to be turned on or off.

14. The apparatus of claim 3, wherein the target comprises a programmable digital pattern generator having a programmable pattern selection array that enables a pattern to be imprinted onto the electron beam thereby forming a patterned electron beam.

15. The apparatus of claim 3, wherein the target comprises a programmable digital pattern generator having a programmable pattern selection array that enables a pattern to be imprinted onto the electron beam thereby forming a patterned electron beam that is directed onto a subject.

16. The apparatus of claim 15, wherein the subject comprises a semiconductor wafer arranged in the path of the patterned electron beam to enable patterning of the wafer.

17. The apparatus of claim 15, wherein the subject comprises a mask substrate arranged in the path of the patterned electron beam to enable the formation of a mask pattern on the mask substrate.

18. The apparatus of claim 15, wherein the cross-sectional area of the electron beam has approximately the same dimension as the programmable pattern selection array of the pattern generator.

19. The apparatus of claim 15, wherein
the programmable pattern selection array is set at a first base voltage level; and
the cathode control amplifier regulates the voltage level at the shaped cathode to regulate the potential of the electron beam such that the potential is controllably varied from the first base voltage level.

20. The apparatus of claim 19, wherein the cathode control amplifier regulates the voltage level of the electron beam at the shaped cathode so that,
when the potential of the electron beam is set at a selected second voltage level negative relative to the first base voltage level the electron beam is entirely absorbed by the programmable pattern selection array such that no electron beam is produced by the programmable pattern selection array and
when the potential of the electron beam is set at a third level, positive relative to the first base voltage level, the electron beam is selectively reflected by the programmable pattern selection array such that a patterned electron beam is produced by the programmable pattern selection array.

21. The apparatus of claim 2, wherein the cathode control circuitry controls the cathode control amplifier using an optical link between the cathode control circuitry and the cathode control amplifier.

22. The apparatus of claim 21, wherein the optical link cathode control circuitry includes a controllable pulse generator that can be adjusted to achieve a desired duty cycle in the cathode control amplifier.

23. The apparatus of claim 22, wherein the pulse generator includes a laser element that produces an optical control signal that passes through a fiber optic line of the optic link to an optical receiver of the cathode control amplifier to enable the transmission of control information to the amplifier.

24. An apparatus comprising:
a cathode suitable for producing electrons to enable the generation of an electron beam;
a cathode activation source configured to selectively activate the cathode to produce the electrons of the electron beam;
a focusing electrode configured to accelerate the electrons of the electron beam and selectively pass the electron beam through an aperture of the focusing electrode;
a cathode control amplifier for regulating the voltage level at the cathode and thereby regulate the potential of the electron beam; and
control circuitry configured to adjust the cathode control amplifier to enable regulation of the potential of the electron beam and adjust the a voltage at the aperture to selectively shut the electron beam on or off.

25. A blanker apparatus comprising:
a cathode that emits electrons when exposed to radiation, the cathode for generating an electron beam having a shaped cross-section;
a cathode activation source for controllably activating the cathode to produce the electron beam; and
control circuitry configured to adjust the cathode activation source to regulate the electron beam produced by the shaped cathode.

26. The apparatus of claim 25, wherein the cathode is configured as a shaped cathode such that when the shaped cathode is activated by the cathode activation source it produces an electron beam having a shaped cross-section associated with the shape of the shaped cathode.

27. The apparatus of claim 25 wherein:
the cathode comprises a photoemissive cathode;
the cathode activation source comprises a laser beam directed onto the cathode to produce the electrons of the electron beam; and
the control circuitry modulates the laser to regulate the electron beam produced by the cathode.

28. The apparatus of claim 27, wherein the control circuitry modulates the laser to enable a repetition rate of at least 200 MHz and to enable a switching speed of less than about 50 picoseconds in the electron beam.

29. The apparatus of claim 27, wherein the control circuitry modulates the laser to enable a repetition rate of at least 1 GHz and to enable a switching speed of less than about 35 picoseconds in the electron beam.

30. The apparatus of claim 25 wherein:
the cathode comprises a photoemissive cathode;
the cathode activation source comprises an optical beam directed onto the cathode to produce the electrons of the electron beam; and
the control circuitry modulates the optical beam to regulate the electron beam produced by the cathode.

31. The apparatus of claim 25, wherein during operation, the cathode activation source activates the cathode such that the blanker produces a continuous electron beam that is directed onto a target.

32. The apparatus of claim 31, wherein the target comprises a programmable digital pattern generator having a programmable pattern selection array that enables a pattern to be imprinted onto the electron beam thereby forming a patterned electron beam that is directed onto a semiconductor wafer to enable patterning of the wafer.

33. The apparatus of claim 32, wherein the control circuitry modulates the laser to enable a duty cycle of at least 200 MHz and to enable a rise time of less than about 35 picoseconds in the electron beam produced by the cathode.

34. A method for performing high speed blanking in a reflection electron beam lithography device, the method comprising:
activating a photo cathode with a laser to generate an intermittent electron beam;
directing the intermittent electron beam onto a digital pattern generator, the generator including an array of programmable elements configured to selectively imprint patterns onto the intermittent electron beam to form patterned electron beam;
adjusting the elements of the array of programmable elements to selectively imprint patterns onto the intermittent electron beam enabling the formation of the patterned electron beam; and
modulating the laser output to controllably gate the production of electrons by the photo cathode such that when the laser is off the intermittent electron beam is off and no patterned electron beam is produced and such that when the laser is on the intermittent electron beam is on and the patterned electron beam is produced.

35. A method for performing high speed blanking in a reflection electron beam lithography device, the method comprising:
activating a cathode to generate an continuous electron beam;
directing the continuous electron beam onto a digital pattern generator, the generator including an array of programmable elements configured to selectively imprint patterns onto the continuous electron beam to form patterned electron beam;
adjusting the elements of the array of programmable elements to selectively imprint patterns onto the continuous electron beam enabling the formation of the patterned electron beam; and
modulating the voltage level at the cathode to controllably adjust the potential of the continuous electron beam such that when the voltage level is biased to a first voltage level no patterned electron beam is produced and such that when the voltage level is biased to a second voltage level the patterned electron beam is produced.

36. The method of claim 35, wherein continuous electron beam has an energy spread of less than about 0.25 volts at the cathode.

37. The method of claim 35, wherein activating the cathode to generate a continuous electron beam comprises activating a shaped cathode to generate a continuous electron beam having a shaped cross-section.
